(19) United States
(12) Patent Application Publication
(10) Pub. No.: US 2011/0058342 A1
(43) Pub. Date: Mar. 10, 2011

(54) Semiconductor Device

(75) Inventors: Shinya Kawakita, Tokyo (JP); Shiro Yamashita, Yokohama (JP); Ukyo Ikeda, Fujisawa (JP); Takuto Yamaguchi, Toride (JP)

(73) Assignee: Hitachi, Ltd., Tokyo (JP)

(21) Appl. No.: 12/868,303

(22) Filed: Aug. 25, 2010

(30) Foreign Application Priority Data
Sep. 9, 2009 (JP) 2009-207685

(51) Int. Cl. H05K 7/00

(52) U.S. Cl. 361/735

(57) ABSTRACT

An object of the present invention is to provide a semiconductor device having a small-sized, thin, and high heat-dissipating multilayer frame mounting structure. To achieve the object, the invention provides a semiconductor device having a multilayer frame obtained by stacking a plurality of lead frames on which electronic parts are mounted and sealing the stack with a resin. An interlayer distance between a lead frame on which an electronic part is mounted and a lead frame which is stacked above the lead frame and on which an electronic part is mounted is shorter than a distance from a face of the lead frame to a top face of the electronic part.

### BACKGROUND OF THE INVENTION

1. Field of the Invention

The present invention relates to a semiconductor device having a multilayer frame mounting structure.

2. Description of the Related Art

A so-called power module obtained by mounting an electronic part such as a power semiconductor device (whose power consumption is 0.1 watt or greater) typified by a power MOSFET, an IGBT, or the like on a wiring board is generally used in an in-vehicle semiconductor device and an industrial semiconductor device. The power module has a structure of discharging heat by transferring heat from a face on the side opposite to a face on which a power semiconductor device is mounted to a cooling plate of a casing or the like to which the power module is fixed.

Conventionally, an electronic control unit using a power module is provided for each device to be controlled. However, in recent years, those electronic control units are requested to realize miniaturization, integration, and lower cost. Miniaturization is required also for the power module.

Multilayer frame mounting structures realizing miniaturization are disclosed in, for example, Japanese Patent Application Laid-Open Publication Numbers H5-47559, 2001-77488, 2005-56982, 2005-101262, H6-291362, and H9-233649.

### SUMMARY OF THE INVENTION

Since the conventional technique of providing multilayers for a conventional wiring board has problems such as increase in cost and enlargement of the board area, a multilayer lead frame mounting structure is proposed. Japanese Patent Application Laid-Open Publication Numbers H5-47559 and 2001-77488 disclose a technique of sealing each of lead frames on which electronic parts and the like are mounted with a resin and staking the lead frames, and electrically connecting the lead frames. In the technique, however, the resin layer between the lead frames becomes thick, and there is the possibility that an air layer interposes between the lead frames. It causes a problem that heat dissipation drops.

Japanese Patent Application Laid-Open Publication Numbers 2005-56982 and 2005-101262 disclose a technique of separately forming a lead frame on which a power-related part to which large current (power) is transmitted and a lead frame on which a control-related part having a small current amount (power) is mounted and staking the lead frames. In the technique, however, an electronic part is mounted on a lead frame in which an insulating resin is filled in an isolation trench and, after stacking, the entire module is sealed with a resin. At the time of resin sealing, air, a foreign matter, and the like tend to be enclosed in a center portion in the thickness direction or a plane direction of the lead frame, the periphery of a large part, and the like, and heat dissipation deteriorates. There is also a problem that electric reliability deteriorates. Further, by classifying a lead frame on which a part is to be mounted on the basis of the size of the part, there is also a problem that flexibility in designing of a semiconductor device drops.

Japanese Patent Application Laid-Open Publication No. H6-291362 discloses a technique of attaching a lead frame for heat dissipation to a lead frame on which an electronic part is mounted. Japanese Patent Application Laid-Open Publication No. H9-233649 discloses a technique of improving heat dissipation by connecting a lead frame on which an electronic part is mounted and a lead frame for heat dissipation with an electric-insulating and thermal-conducting material. The technique, however, has a problem such by providing the lead frame for heat dissipation on which no electronic part is mounted, the area in which electronic parts can be mounted is narrowed, and miniaturization of the power module is suppressed.

In view of the problems, an object of the present invention is to provide a semiconductor device having a small, thin, and highly-heat-dissipating multilayer frame mounting structure.

To achieve the object, the present invention provides a semiconductor device including: first and second electronic parts; a lead frame in a first layer on which the first electronic part is mounted; a lead frame in a second layer which is stacked above the lead frame in the first layer and on which the second electronic part is mounted; and a sealing resin sealing the lead frames in the first and second layers and the first and second electronic parts. The first electronic part is mounted on a face opposite to the lead frame in the second layer, of the lead frame in the first layer, and a distance between the lead frame in the first layer and the lead frame in the second layer is shorter than a distance from the lead frame in the first layer to a top face of the first electronic part.

The present invention can provide a semiconductor device having a small and highly-heat-dissipating multilayer frame mounting structure.

### BRIEF DESCRIPTION OF THE DRAWINGS

The present invention will become fully understood from the detailed description given hereinafter and the accompanying drawings, wherein:

FIG. 1 is a side view schematically showing a semiconductor device having a multilayer frame mounting structure in a first embodiment;

FIG. 2 is a perspective view of a main portion around lead frames in first and second lead frames in the first embodiment;

FIG. 3 is a side view of the main portion shown in FIG. 2;

FIG. 4 is a side view of a first comparative example as a conventional multilayer lead frame mounting structure;

FIG. 5 is a diagram showing comparison between module thickness of the first embodiment and that of the first comparative example;

FIG. 6 is a diagram showing comparison between a temperature rise value of an electronic part mounted on the lead frame in the first layer in the first comparative example and that in the first embodiment;

FIG. 7 is a top view of the first layer in the multilayer lead frame module shown in FIG. 1;

FIG. 8 is a top view of a second layer in the multilayer lead frame module shown in FIG. 1;

FIG. 9 is a top view of a third layer in the multilayer lead frame module shown in FIG. 1;

FIG. 10 is a flowchart of manufacture of the multilayer lead frame module performed in the first embodiment;

FIG. 11 shows a lead frame in the first layer immediately after formation of a circuit pattern, in the lead frame module illustrated in FIG. 1;

FIG. 12 is a top view of the lead frame in the first layer in a state where an electronic part and electronic parts other than the electronic part such as a chip part are mounted by using a conductive material on the lead frame after formation of the circuit pattern shown in FIG. 11, and a bridge is cut;

FIG. 13 is a top view of the lead frame in the first layer in a state where the multilayer lead frame module is sealed with a sealing resin and, after that, the tie bar is cut;

FIG. 14 is a side view schematically showing a semiconductor device having another multilayer frame mounting structure;

FIG. 15 shows a result of comparison between a temperature rise value of an electronic part mounted in a first lead frame in a second embodiment and that of an electronic part mounted in a first lead frame in a first comparative example;

FIG. 16 shows an example of the relation between the voltage difference between a source electrode and a drain electrode and temperature;

FIG. 17 is a cross section of a main portion of a lead frame module in which a resin having relative permittivity higher than that of a sealing resin is applied between a ground potential face of a lead frame in the second layer and a rectangular parallelepiped made of copper, opposed to the ground potential face of the lead frame in the second layer and ultrasonic-bonded to a signal terminal of the lead frame in the first layer, and which is entirely sealed with a sealing resin;

FIG. 18 is a diagram showing the relation between a distance between a ground potential face and an opposing signal terminal of a lead frame and capacitance in a third embodiment;

FIG. 19 is a side view of a main portion of a semiconductor device having a lead frame structure obtained by covering a space between a tip portion of two leads extending from an electronic part and the leads with a resin and sealing the whole with a sealing resin; and

FIG. 20 is a right side view of the main portion shown in FIG. 19.

### DESCRIPTION OF THE PREFERRED EMBODIMENTS

The present invention will be described by the embodiments below.

### First Embodiment

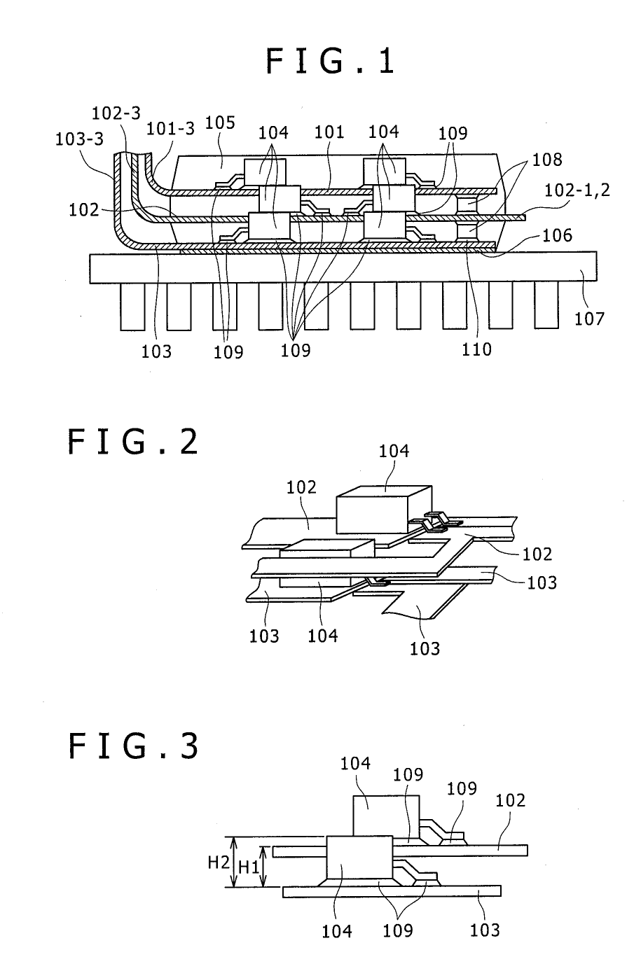

A first embodiment will be concretely described with reference to FIGS. 1 to 13. FIG. 1 is a side view schematically showing a semiconductor device having a multilayer frame mounting structure in the first embodiment.

As shown in FIG. 1, a lead frame 101 in a first layer, a lead frame 102 in a second layer, and a lead frame 103 in a third layer, on which a plurality of electronic parts 104 are mounted are stacked, entirely sealed with a sealing resin 105, and fixed to a casing 107 via a heat dissipation sheet 106 with bolts (not shown in FIG. 1), thereby manufacturing a multilayer lead frame module. In FIG. 1, reference numeral 108 denotes a lead frame interlayer connecting member, reference numeral 101-3 denotes a signal input terminal constructed by the lead frame in the first layer, reference numeral 102-1 denotes a large-current input terminal constructed by the lead frame in the second layer, reference numeral 102-2 denotes a large-current output terminal constructed by the lead frame in the second layer, reference numeral 102-3 denotes a signal input terminal constructed by the lead frame in the second layer, and reference numeral 103-3 denotes a signal input terminal constructed by the lead frame in the third layer. Reference numeral 109 denotes a conductive material used for electric connection, mechanical connection, and the like between the electronic part 104 and the lead frames 101, 102, and 103, and reference numeral 110 denotes a conductive material having a melting point lower than that of the conductive material 109.

The electronic part 104 shown here is a semiconductor device (such as a power MOSFET, IGBT, or diode) for controlling/supplying power source or power to drive a motor by converting alternate current to direct current, increasing the voltage, or the like, charge a battery, operate a microcomputer and an LSI, and the like. As other electronic parts (not shown in FIG. 1), there are a coil, a capacitor, and a resistor.

A copper alloy (Cu-0.1 Fe-0.03P (wt %)) having a thickness of 1.0 mm is used for the lead frames 101, 102, and 103 in the first, second, and third layers, and a circuit pattern is formed by press work. A lead frame which can be used in the embodiment is a metal plate containing, as a main component, other than Cu (copper), Al (aluminum), Ni (nickel), or Fe (iron). Although the thickness is generally 0.2 mm to 2.0 mm, it is preferably 0.5 mm or greater from the viewpoint of thermal conductivity. By an isolation trench penetrating the metal plate in the thickness direction, a desired circuit can be formed. To improve adhesion between the lead frame and the sealing resin, the surface of the lead frame may be plated with Ni (nickel), Sn (tin), solder, or the like.

As the conductive material solder (Sn-3.0 Ag-0.5 Cu (wt %)) is used. As the conductive material 109, it is sufficient to use a material having a melting temperature higher than that of the conductive material 110. The reason is that when the interlayer connecting member 108 and each of the lead frames 101, 102, and 103 are connected, the conductive material 109 for electrically connecting and mechanically fixing the electronic parts is prevented from being melted. Although the conductive material used in the embodiment is not limited as long as it can simultaneously perform electric connection and mechanical fixing by heating process, it is, preferably, solder or a conductive paste for the reason that the conductive material can be applied on the lead frame by printing or a dispenser and productivity is high. For example, in the case of using solder, any solder is used as long as its melt start temperature is equal to or higher than the effective treatment temperature of the sealing resin. As the solder, for example, a solder of an Sn (tin)-Au (gold) alloy, a solder of Sn (tin)-Pb (lead) alloy, a solder of Sn (tin)-Ag (silver) alloy, a solder of Sn (tin)-Ag (silver)-Cu (copper) alloy, and a solder of Sn (tin)-Ag (silver)-Bi (bismuth) alloy and solders of alloys obtained by adding 5 wt %) or less of In (indium), Ni (nickel), Sb (antimony), Bi (bismuth), or the like to any of the alloys are used. The conductive paste is obtained by mixing a conductive material and an adhesive material.

In the case of using the conductive paste, although the conductive material is not limited, any one of or a combination of two or more of metal materials such as Ag (silver), Cu (copper), Sn (tin), Pb (lead), Al (aluminum), Pt (platinum), and Au (gold), organic materials such as polyacetylene, carbons such as black lead, fullerene, and carbon nanotube, and a carbon compound is/are used. In the case of using a thermosetting resin as an adhesive component, an epoxy resin, an acrylic resin, a bismaleimide resin, or the like is used. In the case of using a thermoplastic resin as an adhesive component, it is not limited as long as a resin obtained by dissolving a resin whose melting point is 250° C. or higher such as thermoplastic polyimide, polyetherimide, polyamide-imide in an organic solvent whose boiling point is 100° C. to 300° C. is used.

As the sealing resin 105, a resin having, as main components, a biphenyl epoxy resin and Al₂O₃ (aluminum oxide) is used. As the sealing resin, a thermosetting resin composition which can be molded is sufficient. Particularly, an epoxy resin composition having an epoxy resin, a hardener, a hardening accelerator, and an inorganic filler is desirable. Any epoxy resin composition may be used as long as it has two or more epoxy groups per molecule. Examples of the epoxy resin composition include o-cresol novolak epoxy resin, naphthalene epoxy resin, dicyclopentadiene epoxy resin, bromine epoxy resin, biphenyl epoxy resin, bisphenol A epoxy resin, and bisphenol F epoxy resin. A biphenyl epoxy resin having low melt viscosity is preferable. The hardener is not limited as long as it has a functional group that hardens an epoxy resin such as phenolic hydroxyl, amino group, carbonyl group, or acid anhydride group. For example, phenolic novolak, xylylene phenol resin, dicyclopentadiene phenol resin, or cresol phenolic novolak may be used. Phenolic novolak having low melt viscosity is preferable.

As the inorganic filler, an oxide such as SiO₂ (silica), Al₂O₃ (aluminum oxide), MgO (magnesium oxide), or BeO (beryllium oxide), a nitride such as Si₃N₄ (silicon nitride), BN (boron nitride), or AlN (aluminum nitride), AlSiC (aluminum silicon carbide), or the like is used. Among them, SiO₂ (silica) having good balance in a mechanical characteristic, hardening property, corrosion resistance property, and the like is desirable. Although SiO₂ (silica) includes molten SiO₂ (silica) and crystalline SiO₂ (silica), molten SiO₂ (silica) having smaller coefficient of thermal expansion is preferred. Although the shape of a particle may be a spherical, angular, or scale shape, a spherical shape having high fluidity is preferable. As electrical insulation, it is sufficient that volume resistivity at 25° C. is 1×10̂10 (the tenth power of 10) Ω·cm or higher. Preferably, 95 wt % or higher of the inorganic filler is spherical powders each having a diameter lying in the range from 0.1 to 100 μm and whose average diameter is 2 to 20 μm. The maximum filling fraction of the filler in this range is high. Even the filling fraction is high, the melt viscosity of the epoxy resin composition does not easily increase. The filling amount of the inorganic filler is preferably 50 vol % or higher of the total volume of the epoxy resin composition excluding the components of a solvent which volatilizes during hardening by heating for the reason that the amount of a corrosive component which can exist in the sealing material becomes smaller.

In the case of an epoxy resin, the kind of the hardening accelerator is not limited as long as the hardening accelerator accelerates a hardening reaction. Examples include phosphorous compounds such as triphenylphosphine, triphenylphosphine-triphenyl boron, tetraphenyl phosphonium-tetraphenylborate, butyltriphenylphosphonium-tetraphynylborate, and the like, imidazole compounds such as 2-phenyl-4-benzil-5-hydroxymethylimidazole, and 2-phenyl-4-methyl-5-hydroxymethylimidazole, and 2-ethyl-4-methylimidazole, amine compounds such as 1,8-diazabicyclo[5.4.0]undecene-7, and diaminodiphenylmethane, and triethylene diamine, and the like. To the epoxy resin composition, as necessary, a mold release agent, a coloring agent, a flexibilizer, a fire retardant aid agent, a solvent, or the like can be added.

For the resin sealing molding method, transfer molding, injection molding, potting molding, or the like can be used. Among them, transfer molding is preferable for the reason that it is excellent in productivity and reliability. In the case of performing the transfer molding using an epoxy resin composition, the molding temperature is set to be 150° C. or higher and less than 200° C. At a temperature less than 150° C., a hardening reaction is slow and mold releasability is low. To increase the mold releasability, long molding time is necessary, and productivity deteriorates. At 200° C. or higher, the hardening reaction advances quickly and flowability deteriorates, so that the resin is not filled. Consequently, molding is performed normally at a molding temperature around 175° C.

As the heat dissipation sheet 106, a resin sheet using, as main components, silicone resin and Al₂O₃ (aluminum oxide) as an inorganic filler is used. For the heat dissipation sheet, except for a silicone resin, an olefin resin or the like may be used. It is sufficient to select a resin on the basis of the use environments such as heatproof temperature. As the inorganic filler, except for Al₂O₃ (aluminum oxide), an oxide such as SiO₂ (silica), MgO (magnesium oxide), or BeO (beryllium oxide), a nitride such as Si₃N₄ (silicon nitride), BN (boron nitride), or AlN (aluminum nitride), AlSiC (aluminum silicon carbide), or the like is used. Among them, Al₂O₃ (aluminum oxide) is desirable from the viewpoint of thermal conductivity, particle shape, and the like. A heat dissipation grease may be used if it has a composition similar to that of the heat dissipation sheet.

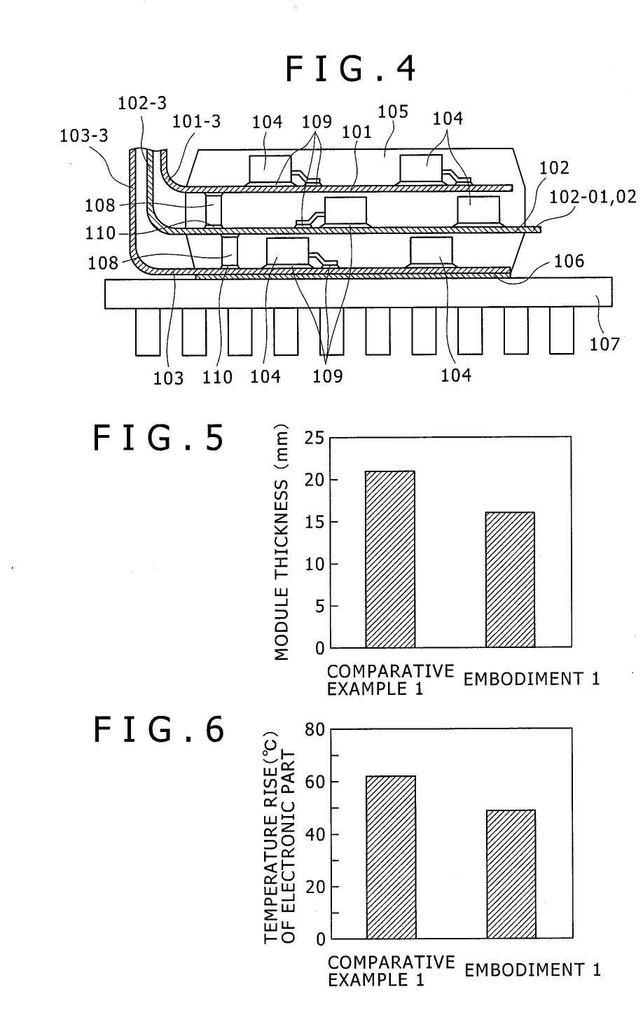

FIG. 2 is a perspective view of a main portion around the lead frames 101 and 102 in the first and second layers in FIG. 1 (the conductive material 109 is shown). By disposing the electronic part 104 mounted on the lead frame 102 so as to exist between the circuit patterns constructed by the lead frames 101, a distance H1 between the lead frames 101 and 102 is made shorter than a distance H2 from the lead frame face on which the electronic part 104 is mounted to the top face of the electronic part 104. In the embodiment, the distance H2 from the lead frame face on which the electronic part 104 is mounted to the top face of the electronic part 104 is about 5 mm. A drain electrode of the electronic part 104 has a size of about 10 mm by 10 mm. FIG. 3 is a side view of the main portion shown in FIG. 2. The distance H1 between the lead frame in the first layer and the lead frame in the second layer is 4 mm. FIG. 4 is a side view of a first comparative example as a conventional multilayer lead frame mounting structure. In the case of mounting the same electronic part as the electronic part 104 used in the first embodiment in the conventional structure, the distance H1 between the lead frames is about 6 mm.

FIG. 5 is a diagram showing comparison between module thickness of the first embodiment and that of the first comparative example. The module thickness denotes a distance from the face on the side opposite to the electronic part mounting face of the lead frame 103 in the third layer to the top face of the multilayer lead frame module sealed with the sealing resin 105. By setting the distance H1 between the lead frames to be shorter than the distance H2 from the lead frame face on which the electronic part is mounted to the top face of the electronic part, the entire module thickness can be reduced. The thermal resistance between the lead frames is reduced, and the heat dissipation property of the electronic part 104 mounted on the lead frame 101 in the first lead frame and the electronic part 104 mounted on the lead frame 102 in the second layer can be improved as compared with that in the multilayer lead frame mounting structure in the first comparative example. FIG. 6 is a diagram showing comparison between a temperature rise value of the electronic part mounted on the lead frame in the first layer in the first comparative example and that in the first embodiment. As shown in FIG. 6, the temperature rise of the electronic part 104 mounted on the lead frame 101 in the first layer in the first comparative example is greater than that of the electronic part 104 mounted on the lead frame 101 in the first layer in the structure of the first embodiment.

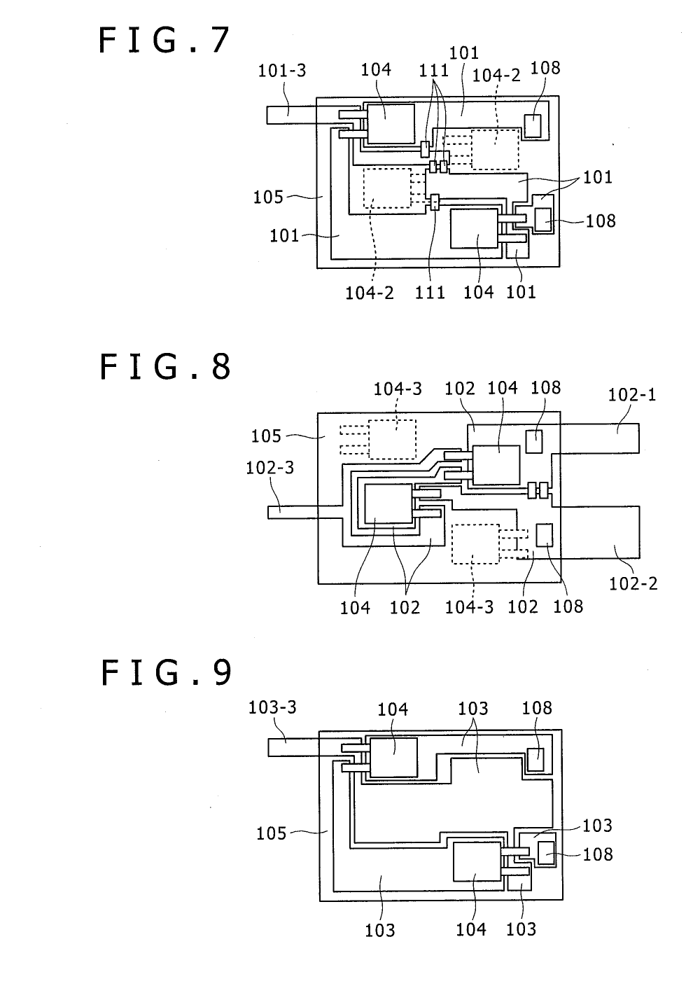

FIG. 7 is a top view of the first layer in the multilayer lead frame module shown in FIG. 1. On the lead frame 101 in the first layer, a plurality of electronic parts 104 and a plurality of chip parts (such as a shunt resistor and a chip capacitor which are not shown) are mounted via the conductive material 109 (not shown).

Reference numeral 101-3 denotes a signal transmission terminal which is constructed by the lead frame 101 in the first layer. The signal transmission terminal 101-3 is electrically connected to an electrode for controlling the on/off state of the electronic part 104, for example, is connected to the gate electrode of a power MOSFET or IGBT and used for controlling the electronic part 104. Further, with the interlayer connecting member 108, the lead frame 101 in the first layer and the lead frame 102 in the second layer are electrically connected. Reference numeral 105 denotes the sealing resin. Reference numeral 104-2 denotes a mounting position of the electronic part 104 mounted on the lead frame 102 in the second layer. By forming a circuit pattern that the lead frame 101 in the first layer skirts the mounting position 104-2 of the electronic part 104 mounted on the lead frame 102 in the second layer, the distance H1 between the lead frame 101 in the first layer and the lead frame 102 in the second layer is made shorter than the distance H2 from the lead frame face on which the electronic part 104 is mounted to the top face of the electronic part 104. By thermally connecting the signal transmission terminal 101-3 to a casing and a heat dissipation fin on the outside of the sealing resin, the heat dissipation property of the multilayer lead frame module can be improved. Thermal connection means that the equivalent thermal conductivity of a connecting part is equal to or higher than the thermal conductivity of the atmosphere. To thermally connect the signal terminal to the casing, the heat dissipation fin, or the like, it is sufficient to use ultrasonic bonding, welding, or metal bonding with solder or the like, and one of highly thermal conductive resin plastic materials. It is more preferable to use the ultrasonic bonding or welding in which an air layer or an inclusion does not exist between the signal terminal and the casing. As the interlayer connecting member 108, a copper alloy (Cu-0.1Fe-0.03P (wt %)) having a horizontal size of 5 mm, a vertical size of 5 mm, and a height of 7 mm is used. The interlayer connecting member which can be used for the embodiment is a cube containing, as a main component, except for Cu (copper), Al (Aluminum) or Ni (Nickel). To improve adhesion between the interlayer connecting member and the sealing resin, the surface of the interlayer connecting member may be plated with Ni (nickel), Sn (tin), solder, or the like.

FIG. 8 is a top view of a second layer in the multilayer lead frame module shown in FIG. 1. Like the lead frame in the first layer, two electronic parts 104 are mounted on the lead frame 102 in the second layer via the conductive material 109 (not shown). The lead frame 102 in the second layer is provided with the large-current input terminal 102-1 as a power system from the outside, the output terminal 102-2, and the signal transmission terminal 102-3. The current supplied from the large-current input terminal 102-1 is passed to the lead frame on which a plurality of electronic parts (the power MOSFET, IGBT, and the like) 104 in the on state are mounted and to a plurality of chip parts 111 (shunt resistor, chip capacitor, and the like) mounted on the lead frame on which the plurality of electronic parts (the power MOSFET, IGBT, and the like) 104 in the on state are mounted. Reference numeral 104-3 indicates a mounting position of the electronic part 104 mounted on the lead frame 103 in the third layer. In the lead frame 102 in the second layer, a circuit pattern is formed while skirting the mounting position 104-3 of the electronic part 104 mounted on the lead frame 103 in the third layer.

FIG. 9 is a top view of a third layer in the multilayer lead frame module shown in FIG. 1. Like the lead frame in the first layer, two electronic parts 104 are mounted on the lead frame 103 in the third layer via the conductive material 109 (not shown). Reference numeral 103-3 denotes a signal transmission terminal, is constructed by the lead frame 103 in the third layer, and electrically connected to an electrode for controlling the on/off state of the electronic part 104.

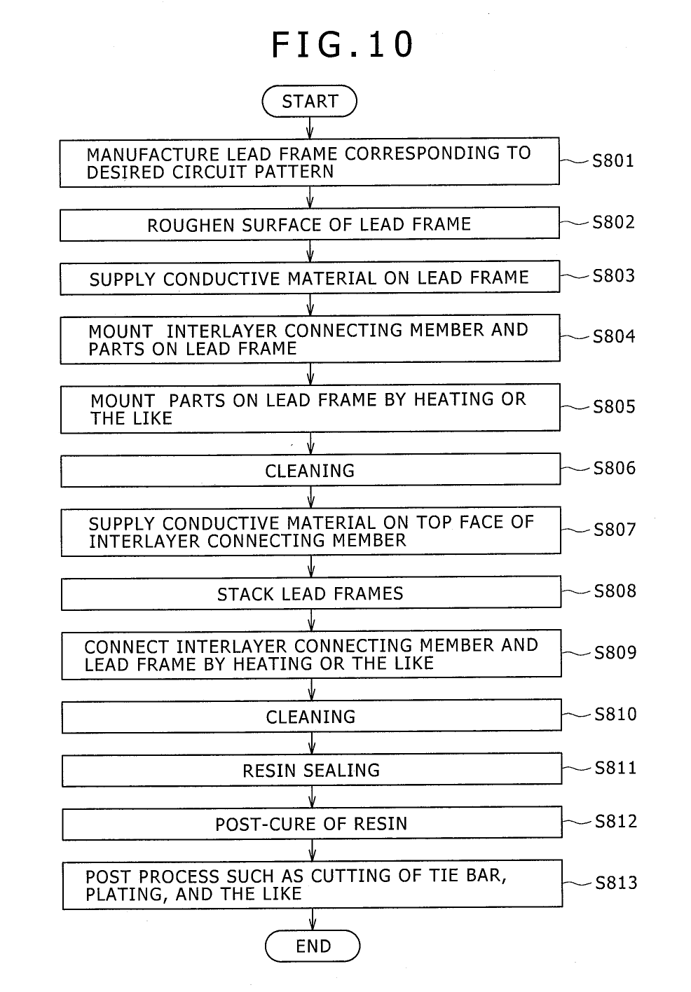

FIG. 10 is a flowchart of manufacture of the multilayer lead frame module performed in the first embodiment. First, a lead frame corresponding to a desired circuit pattern is manufactured (S801). In the embodiment, a circuit pattern is formed by press work. A desired circuit pattern may be formed in the lead frame by etching in place of the press work. The thickness of the lead frame in which the circuit pattern is formed by etching is, preferably, 2.0 mm or less, more preferably, 1.5 mm or less. By setting the thickness to 1.5 mm or less, the pattern can be formed with precision of 10% or less of the dimensions.

After that, the surface of the lead frame is roughened (S802). In the embodiment, sandblasting of injecting abrasive called “Zircon grid” at an injection pressure of 0.25 MPa is used. After the surface roughening, the conductive material 109 is supplied onto the lead frame by a dispenser (S803). Subsequently, the interlayer connecting material is applied on the lead frames in the second and third layers and the electronic parts are mounted on the lead frames (S804). After mounting the electronic parts on the lead frames, the electronic parts and the lead frames are electrically and mechanically connected by heating (S805).

After the connection, Ar (argon) plasma cleaning is performed (S806). As cleaning parameters, the Ar (argon) flow rate is set to 8 sccm, pressure is set to 12 Pa, and treatment time is set to 180 seconds. After the cleaning, the conductive material 110 having a melting point lower than that of the conductive material 109 supplied onto the lead frame is supplied to the top face of the interlayer connecting material by the dispenser (S807). After that, three lead frames are stacked (S808) and connected to each other by heating (S809). Ar (Argon) plasma cleaning with the same parameters as those of the above-described cleaning is performed (S810). After the cleaning, the resultant is sealed with a sealing material (S811). For the sealing, a transfer molding machine is used. As molding parameters, mold temperature is set to 180° C., transfer pressure is set to 1500 kg, and molding time is set to three minutes. After completion of the resin sealing, the lead frame module is released from the mold. The sealing material is post-cured for five hours in a thermostat bath of 175° C. (S812). Finally, a tie bar as the lead frame other than terminals, existing on the outside of the sealing material 105 is cut, and the terminals are plated with Ni (nickel) (S813).

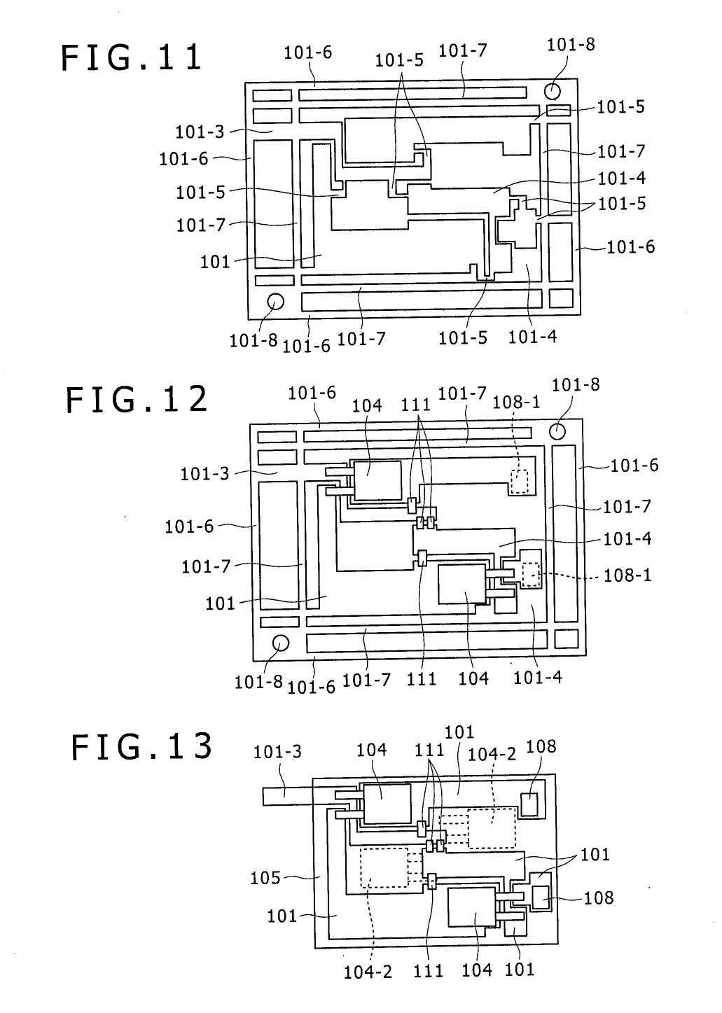

FIG. 11 shows the lead frame 101 in the first layer immediately after formation of a circuit pattern, in the lead frame module illustrated in FIG. 1. A lead frame 101-4 as a floating island is temporarily fixed by a bridge 101-5. The lead frame 101-4 as a floating island refers to a lead frame independent of an outer frame 101-6 of the lead frame except for the bridge 101-5. In FIG. 11, reference numeral 101-7 denotes a tie bar formed by the lead frame in the first layer, and reference numeral 101-8 denotes a through hole for alignment used for stacking and arranging the lead frames.

FIG. 12 is a top view of the lead frame in the first layer in a state where the electronic part 104 and electronic parts 111 other than the electronic part 104 such as a chip part are mounted by using the conductive material 109 (not shown in FIG. 12) on the lead frame 101 after formation of the circuit pattern shown in FIG. 11, and the bridge 101-5 is cut. Reference numeral 108-1 denotes a position in which the interlayer connecting member 108 is connected to the lead frame 101 in the first layer.

FIG. 13 is a top view of the lead frame in the first layer in a state where the multilayer lead frame module is sealed with the sealing resin 105 and, after that, the tie bar 101-7 is cut. The tie bar 101-7 is made by a part of the lead frame 101 in the first layer in order to stop outflow of the sealing resin 105 at the time of sealing, and has a width of 1.5 mm in the embodiment.

In the embodiment, the sandblast method is used for roughening the surface of the lead frame. Not only in the embodiment but generally, for example, a blackening process or a process with a surface roughening agent is also effective. Although the rectangular parallelepiped made of copper is electrically connected and mechanical fixed to the lead frame with the conductive material in the embodiment, the invention is not limited to the embodiment but another method is also possible. Before electronic parts are mounted, one of faces of a copper rectangular parallelepiped is ultrasonic-bonded to a lead frame. A conductive material is applied to the face on the side opposite to the ultrasonic-bonded face in the copper rectangular parallelepiped. At the time of mounting the electronic part, by simultaneously heating the electronic part and the conductive material applied between the electronic part and the lead frame, the rectangular parallelepiped and the lead frame are electrically connected and mechanically fixed. By ultrasonic-bonding the copper rectangular parallelepiped to the lead frame, the number of conductive materials used in the multilayer lead frame module can be reduced to one. The process management therefore becomes easier. In addition, since the number of heating curing processes on the conductive material decreases, the energy in the multilayer lead frame module fabricating process can be saved.

In the embodiment, the multilayer lead frame package is fixed to the casing 107 by the bolt via the heat dissipation sheet 106 whose main components are the silicone resin having electric insulation and the inorganic filler Al₂O₃ (aluminum oxide). However, the embodiment is not limited to the heat dissipation sheet. A grease having equivalent properties such as thermal conductivity and electric insulation may be used and a heat dissipation grease which can be used by screen printing or can be supplied by a dispenser is more preferable.

As a result, the small-sized, thin, and highly heat-dissipating multilayer lead frame mounting structure can be provided.

The semiconductor device according to the embodiment can be applied to in-vehicle devices such as an electronic control unit for an engine, an electronic control unit for an electrically-assisted power steering, an electronic control unit for an electric brake, a control unit of urban infrastructure for controlling an inverter for railroad use and an elevating machine, and the like.

### Second Embodiment

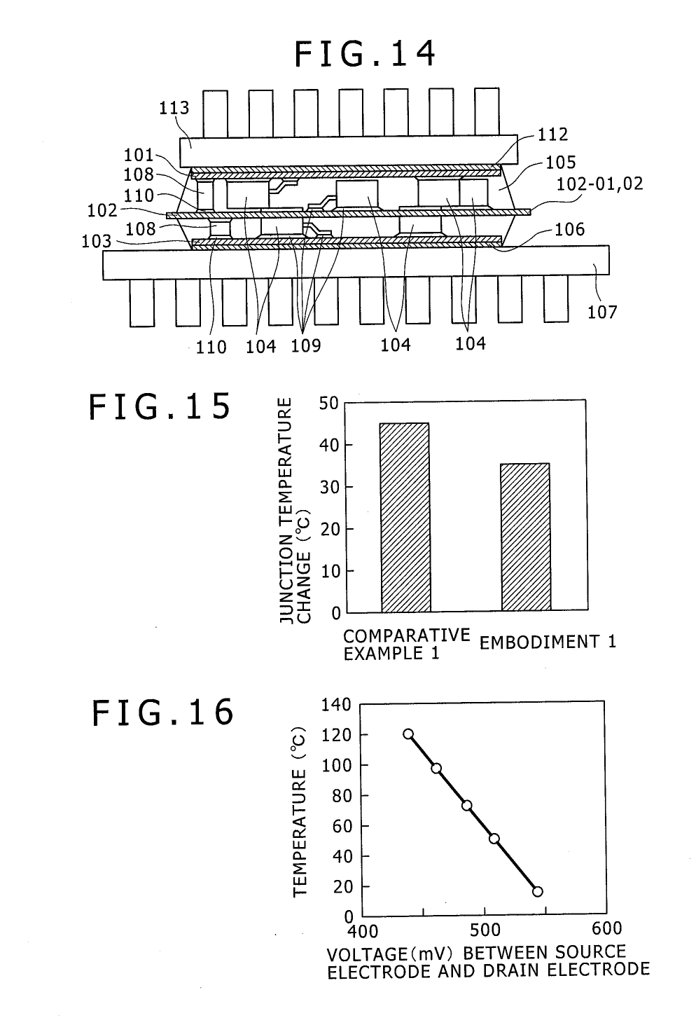

A second embodiment will be described with reference to FIGS. 14 to 16. The matters described in the first embodiment and not described in the second embodiment are similar to those of the first embodiment.

FIG. 14 is a side view schematically showing a semiconductor device having another multilayer frame mounting structure. The same reference numerals as those of FIG. 1 refer to the same components. In the embodiment, layers are stacked so that the face on which the electronic parts 104 and 111 are mounted, of the lead frame 101 in the first layer and the face on which the electronic parts 104 and 111 are mounted, of the lead frame 102 in the second layer face each other, and the entire lead frame module is sealed with the sealing resin 105 so that the face on the side opposite to the face on which the electronic parts 104 and 111 are mounted, of the lead frame 101 in the first layer is exposed from the sealing resin 105. In this case, due to variations in the thickness of the conductive material 109 which electrically connecting and mechanically fixing the interlayer connecting member 108 and each of the lead frames 101, 102, and 103, a part or all of the face on the side opposite to the face on which the electronic parts 104 and 111 are mounted of the lead frame 101 in the first layer may be covered with the sealing resin 105. In this case, by polishing the face on the side opposite to the face on which the electronic parts 104 and 111 are mounted, of the lead frame 101 in the first layer, the face on the side opposite to the face on which the electronic parts 104 and 111 are mounted, of the lead frame 101 in the first layer can be made expose from the sealing resin 105. After that, a heat dissipation fin 113 is mounted by using an adhesive 112 on the face exposed from the sealing resin 105, of the lead frame 101 in the first layer of the multilayer lead frame module manufactured in the second embodiment. As the adhesive, an adhesive having, as main components, silicone resin and Al₂O₃ (aluminum oxide), is used. However, the invention is not limited to the adhesive. Any adhesive having thermal conductivity of 0.2 W/mK or higher can reduce contact thermal resistance between the multilayer frame package and the heat dissipation fin 113, and does not disturb improvement in heat dissipation obtained by using the fin.

FIG. 15 shows a result of comparison between a temperature rise value of the electronic part 104 mounted on the lead frame 101 in the first layer in the second embodiment and that of the electronic part 104 mounted on the lead frame 101 in the first layer in the first comparative example. The temperatures were measured as follows. First, the relation between the voltage difference between the source electrode and the drain electrode and the temperature was measured in the electronic part 104 (power MOSFET) itself whose junction temperature is to be measured. FIG. 16 shows an example of the relation between the voltage difference between a source electrode and a drain electrode and temperature. The value of the electronic part 104 (power MOSFET) used in the embodiment and that of the electronic part 104 (power MOSFET) used in the comparative example 1 are almost the same. The junction temperature is converted from the voltage difference between the source electrode and the drain electrode with reference to FIG. 16.

By making the face on the side opposite to the face on which the electronic parts 104 and 111 are mounted, of the lead frame 101 in the first layer exposed from the sealing resin 105 and mounting the heat dissipation fin 113 via the adhesive 112 as in the embodiment, it was found that the heat dissipation can be improved. As a result, the small-sized, thin, and high heat-dissipating multilayer frame mounting structure can be provided.

### Third Embodiment

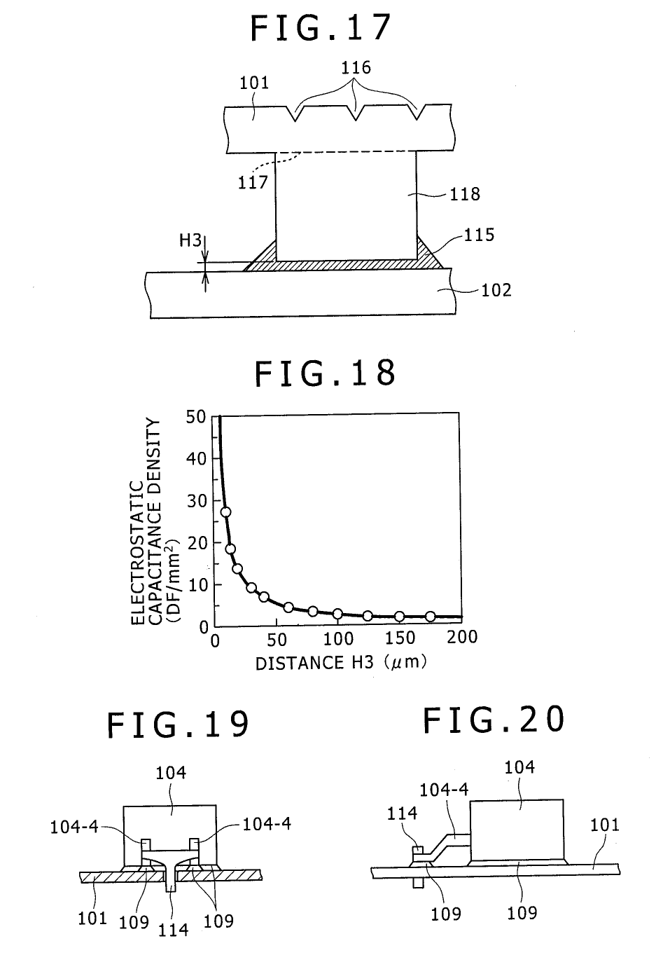

A third embodiment will be described with reference to FIGS. 17 and 18. The matters described in the first and second embodiments and not described in the third embodiment are similar to those of the first and second embodiments.

FIG. 17 is a cross section of a main portion of a lead frame module in which a resin 115 having relative permittivity higher than that of the sealing resin 105 (not shown in FIG. 17) is applied between a ground potential face of the lead frame 102 in the second layer and a rectangular parallelepiped 118 made of copper, opposed to the ground potential face of the lead frame 102 in the second layer and ultrasonic-bonded to a signal transmission circuit of the lead frame 101 in the first layer, and which is entirely sealed with the sealing resin 105 (not shown in FIG. 17). The ultrasonic bonding is performed at room temperature in the atmosphere with parameters that amplitude is 20 μm, ultrasonic oscillation time is 0.5 s, and tool press pressure is 200 MPa. Reference numeral 116 denotes a trace of a tool which oscillates ultrasonic wave at the time of ultrasonic-bonding the copper rectangular parallelepiped 118 to the signal terminal of the lead frame 101 in the first layer. In the case where a burr of the tool trace 116 is largely swollen from the lead frame face, the burr is removed by polishing or the like, the lead frames are stacked, and the entire module is sealed with resin. Reference numeral 117 denotes a bonding interface between the signal transmission circuit of the lead frame 101 in the first layer and the copper rectangular parallelepiped 118. By ultrasonic bonding, there are a part in which the signal transmission circuit of the lead frame 101 in the first layer and the copper rectangular parallelepiped 118 are integrated and a part in which the interface remains. The ground potential face refers to the lead frame face of the same potential as that of the large-current output terminal 102-2 formed by the lead frame in the second layer.

In the embodiment, as the resin 115 having relative permittivity higher than that of the sealing resin 105, a polyimide resin containing an ionic group and a resin whose main component is Al₂O₃ (aluminum oxide) are used. The relative permittivity of the resin used in the embodiment is 30 at 1 MHz when 0.1V is applied. A distance H3 between the ground potential face and the signal terminal of the lead frame facing the ground potential face is set to 20 μm or greater and less than 150 μm, and the resin 115 having relative permittivity higher than that of the sealing resin 105 (not shown in FIG. 17) is applied between the ground potential face and the signal terminal, a capacitance can be formed between the ground potential face and the signal transmission circuit, and noise can be reduced. Specifically, when the distance H3 between the ground potential face and the signal transmission circuit of the lead frame, facing the ground potential face is less than 20 μm or less, electric insulation deteriorates, and a short-circuit failure tends to occur. On the other hand, when the distance H3 between the ground potential face and the signal terminal of the lead frame, facing the ground potential face becomes 150 μm or greater, even when the resin 115 having relative permittivity higher than that of the sealing resin 105 (not shown in FIG. 17) is applied, as shown in FIG. 18, electrostatic capacitance does not increase, and the noise reduction effect does not appear. FIG. 18 is a diagram showing the relation between the distance H3 between the ground potential face and the signal transmission circuit of the lead frame, facing the ground potential face and capacitance in the third embodiment.

By using, as the resin 115 having relative permittivity higher than that of the sealing resin, a composition obtained by making, as necessary, high-permittivity powders contained in a polyimide resin containing an ionic group, an organic solvent capable of dissolving the polyimide resin, water, and an ionic composition having a polarity different from that of the ionic group, the capacitance which is mechanically and chemically stable can be formed.

As the resin 115, an acrylic, epoxy, or polyimide resin as an anionic or cationic polymer resin can be used by itself or a mixture of any combination of those resins can be used. To tackify the polymer resin, a tackifier resin such as a rosin resin, terpene resin, or petroleum resin can be added as necessary. The high-permittivity powders may be made of TiO₂ (titanium oxide), BaTiO₃ (barium titanic acid), Al₂O₂ (aluminum oxide), or the like, but the invention is not limited to those materials. By making one or more of the materials contained in a resin composition, the permittivity between the lead frames can be controlled. Although the dielectric constant of a polyimide resin itself is about 3.5, by making the high-permittivity powders contained, the dielectric constant can be changed to about 20.

As a result, a low-noise, small-size, thin, and high-heat dissipating multilayer lead frame mounting structure can be provided.

### Fourth Embodiment

A fourth embodiment will be described with reference to FIG. 19. Matters described in the first to third embodiments and not described in the fourth embodiment are similar to those of the first to third embodiments.

FIG. 19 is a side view of a main portion of a semiconductor device having a lead frame structure obtained by covering a space between a tip portion of two leads 104-4 extending from the electronic part 104 and the leads 104-4 with a resin 114 and sealing the entire module with the sealing resin 105. FIG. 20 is a right side view of the main portion shown in FIG. 19. As shown in FIGS. 19 and 20, by dropping the resin 114, even when the conductive material 109 used for electric connection and mechanical fixation between the leads 104-4 of the electronic part 104 and the lead frame drops to the lead 104-1 at the time of application or a positional deviation occurs in rotation or the like of the electronic part 104 at the time of melting the conductive material 109, a failure of short-circuit with the lead frame mounted on the lead frame on which the electronic part 104 is mounted can be prevented.

As the resin 114 used in the embodiment, a resin whose volume resistivity at 25° C. is “the tenth power of 10” Ω·cm or higher is used. The other composition and the property of the resin 114 are not limited as long as the resin 114 has adhesion to the sealing resin 105 and the conductive material. It was found out that by using a resin whose volume resistivity is “the tenth power of 10” Ω·cm or higher, even when the resin 114 comes into contact with the lead frame, it does not cause a failure of short-circuit.

It was found out that, a resin as a liquid having, as properties before curing, thixotropy of 1.2 or higher and viscosity of 400 Pa·s or less is dropped by a dispenser and, after that, cured by heating, thereby easily forming a film of the resin having electric insulation property and realizing improved workability.

Thixotropy denotes a value obtained by dividing viscosity at a shear rate of 1 (1/s) at 25° C. by viscosity at a shear rate of 10 (1/s). The viscosity is a viscosity at a shear rate of 10 (1/s) at 25° C. for the following reason. When the thixotropy of a liquid material is smaller than 1.2, the material is not easily applied only to a part of the lead frame at the time of applying the material with a dispenser. When the viscosity of the liquid material is higher than 400 Pa·s, the material does not easily flow at the time of applying the material with a dispenser, and the workability drops.

Concretely, as the liquid material, an epoxy resin, an acrylic resin, a bismaleimide resin, or the like can be used as a main component. As necessary, 0.01 to 50 wt % of insulating particles of ceramics or the like each having a diameter of 1 μm or less may be added to any of the resins. As the liquid material, a material obtained by dissolving a thermoplastic resin such as polyimide, polyetherimide, polyamide-imide, or polyamide in an organic solvent whose boiling point is 100 to 300° C. can be used. As necessary, 0.01 to 50 wt % of insulating particles of ceramics or the like each having a diameter of 1 μm or less may be added to any of the resins. By adding the insulating particles, thermal conductivity, thixotropy, viscosity, and modulus of elasticity can be adjusted.

Although the semiconductor devices each having the multilayer frame mounting structure have been described above in the first to fourth embodiments, the present invention is not limited to the foregoing embodiments but various design changes are possible.

What is claimed is:

1. A semiconductor device comprising:
first and second electronic parts;
a lead frame in a first layer on which the first electronic part is mounted;
a lead frame in a second layer which is stacked above the lead frame in the first layer and on which the second electronic part is mounted; and
a sealing resin sealing the lead frames in the first and second layers and the first and second electronic parts,
wherein the first electronic part is mounted on a face opposite to the lead frame in the second layer, of the lead frame in the first layer, and a distance between the lead frame in the first layer and the lead frame in the second layer is shorter than a distance from the lead frame in the first layer to a top face of the first electronic part.

2. The semiconductor device according to claim 1, wherein the lead frame in the second layer is constructed by a plurality of lead frames, and
the first electronic part is disposed in a space surrounded by the plurality of lead frames in the second layer.

3. The semiconductor device according to claim 1, wherein a face on the side opposite to the face on which the first electronic part is mounted of the lead frame in the first layer is exposed from the sealing resin.

4. The semiconductor device according to claim 1, wherein the lead frame in the first layer and the lead frame in the second layer are connected by an interlayer connecting member, and
the interlayer connecting member is sealed with the sealing resin.

5. The semiconductor device according to claim 4, wherein the lead frame in the first layer and the lead frame in the second layer are electrically connected by the interlayer connecting member.

6. The semiconductor device according to claim 1, further comprising:
a third electronic part; and
a lead frame in a third layer on which the third electronic part is mounted,
wherein the lead frame in the third layer is disposed above the lead frame in the second layer, the third electronic part is mounted on a face opposite to the lead frame in the second layer,
the second electronic part is mounted on a face opposite to the lead frame in the third layer, of the lead frame in the second layer, and
a distance from the lead frame in the second layer to the third electronic part is shorter than a distance to a top face of the second electronic part.

7. The semiconductor device according to claim 6, wherein a face opposite to a face on which the third electronic part is mounted of the lead frame in the third layer is exposed from the sealing resin.

8. The semiconductor device according to claim 3 or 7, further comprising a heat dissipation member connected to an exposed part in the lead frame in the first layer or the lead frame in the third layer.

9. The semiconductor device according to claim 1, wherein a resin having relative permittivity higher than that of the sealing resin exists between the lead frame in the first layer and the lead frame in the second layer.

10. The semiconductor device according to claim 9, wherein one of the lead frames sandwiching the resin having higher relative permittivity is a signal transmission circuit, and the other is a ground circuit.

11. The semiconductor device according to claim 10, wherein a distance between the signal transmission circuit and the ground circuit sandwiching the resin is 20 μm or longer and less than 150 μm.

12. The semiconductor device according to any one of claims 1 to 11, wherein the lead frame in the first layer or the lead frame in the second layer is constructed by a plurality of lead frames, and
the lead frame is connected to another lead frame in the same layer with a resin different from the sealing resin.
